(19) United States
(12) Patent Application Publication
(10) Pub. No.: US 2002/0142252 A1
(43) Pub. Date: Oct. 3, 2002

(54) Method for polysilicon conductor (PC) Trimming for shrinking critical dimension and isolated-nested offset correction

(75) Inventor: Hung Yip Ng, New Milford, NJ (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 09/821,478

(22) Filed: Mar. 29, 2001

(51) Int. Cl. G03F 7/36; C23F 1/00

(52) U.S. Cl. 430/313; 430/311; 430/312; 430/318; 216/58

(57) ABSTRACT

A method of forming a semiconductor device, includes providing a structure having a first critical dimension, forming a lithographic pattern on the structure, and etching the structure with an O₂-containing material to trim the first critical dimension to a second critical dimension, the second critical dimension being smaller than the first critical dimension. Thereafter, any offset between the nested features and the isolated feature can be corrected.

### BACKGROUND OF THE INVENTION

1. Field of the Invention

The present invention generally relates to a method for manufacturing a semiconductor device, and more particularly to an innovative etching process capable of not only extending the gate critical dimension shrinking roadmap with the current lithographic capability without sacrificing the total tolerance control, but also of correcting the inherited isolated-nested offset from lithographic processes.

2. Description of the Related Art

High performance logic devices (e.g., transistors, etc.) rely on aggressive dopant profiles, scaling of the gate dielectric, and scaling of Vdd.

In integrated circuits having field-effect transistors, for example, an important process step is the formation of the gate for each of the transistors, and particularly the dimension of the gate. In many applications, the performance characteristics (e.g., switching speed) and the size of the transistor are functions of the issue (e.g., the width) of the transistor's gate. Thus, for example, a narrower gate tends to produce a high performance transistor (e.g., faster) that is inherently smaller in size (e.g., narrower width).

Thus, typically, such devices have a gate formed on a semiconductor substrate and use a bottom anti-reflective coating to better control the critical dimension (CD) of the gate as defined via a resist mask formed thereon. Precise control of the gate dimension is probably the most critical element for the scaling path.

In order to continue shrinking this scaling path, many techniques have been proposed in recent years for future generation development. Such processes include using a phase shift mask, an attenuated mask, a high numerical aperture (NA) monochromatic lithography tool, an extreme ultraviolet (UV) technique, etc.

However, these techniques are problematic and there are limitations of the conventional lithographic processes and tools which are used to pattern the gates during fabrication.

That is, turning to FIGS. 1A-1D, the complexity of a gate module structure build sequence (and the problems thereof) will be described.

As shown in FIG. 1A, a structure 100 is provided having a polysilicon substrate 101, an antireflection coating (ARC) 102, and a resist pattern 103 formed on the ARC 102. The ARC 102 has a minimum reliable linewidth (e.g., currently in a range of about 0.1 μm to about 1.0 μm). It is noted that the “minimum reliable linewidth” changes from one device generation to a subsequent one. Hence, currently, for example for simplicity, if it desired to control a final line width to 0.1 μm, any line width below 0.06 μm will probably not work since a “short-channel effect” develops. Thus, when controlling to 0.1 μm, the designer must know that the line width must be between 0.06 μm and 0.1 μm. However, going beyond >0.1 μm for the line width is problematic since the device performance becomes poor and the device will not be in the high margin markets. Thus, it is desirable to control the feature (e.g., line width) within the stated range, to further capture the financial returns and to avoid the short channel effect. (As discussed below, the invention trims the device (e.g., a gate) to a small dimension and within a tight tolerance control.).

Returning to FIG. 1B, the ARC 102 (an organic material) is etched via a plasma etching. Such an etch is critical for line width bias and the nested-isolated offset.

For purposes of the present invention, a “nested” feature may be defined as one which has the smallest pitch found in the current device generation technology. These features having the smallest pitch are termed the “most nested features”. For example, the pitch currently may be about 0.25 μm. Hence, a “nested” feature may be separated from another nested feature by the minimum pitch size (e.g., 0.25 μm depending upon the technology).

In contrast, an “isolated” feature is one which is relatively remote and has nothing around it (e.g., not in absolute terms but having nothing around it for 2 μm or more in the current device generation technology). Further, the “nested-isolated offset” refers to the error distance (tolerance) between printing nested features and an isolated feature.

In FIG. 1C, the polysilicon is etched via a gate RIE to achieve a good profile. Such a step must stop on a thin gate oxide 104.

Finally, as shown in FIG. 1D, the resist and ARC are stripped to leave the gate situated on a gate oxide.

Thus, the gate process has much complexity. An ARC etch is critical for line width bias and nested isolated offset. A polysilicon etch (e.g., Gate reactive ion etching (RIE)) must achieve a good profile and stop on a thin oxide as shown in FIG. 1C.

Finally, as shown in FIG. 1C, the resist/ARC are stripped. However, each of these steps is difficult to control and thus difficult to control the dimensions to be smaller and difficult to control the offset of such small dimension printing.

Further, it is noted that the critical path can be corrected with a “hand-picked” (e.g., manual) optimization approach by the circuit designer. However, in general, this technique is very meticulous and time-consuming, and cannot be utilized for a multi-parts fabrication house (i.e., a foundry).

Thus, hitherto the invention, no suitable method has existed for defining the dimension before the gate etching and for controlling the tolerance within the wafers. Indeed, even the lithographic processes have trouble controlling the tolerance (and printing) between isolated features.

### SUMMARY OF THE INVENTION

In view of the foregoing and other problems, drawbacks, and disadvantages of the conventional methods and structures, an object of the present invention is to provide a method for controlling the tolerance of printing isolated features.

Another object is to provide a method for trimming from the existing dimension using an existing tool to a smaller dimension.

Yet another object is to provide a method and technique employing a charging mechanism, thereby to correct the offset.

In a first aspect of the present invention, a method for forming a semiconductor device, includes providing a structure having a first critical dimension, forming a lithographic pattern on the structure, and etching the structure with an O₂-containing material to trim the first critical dimension to a second critical dimension, the second critical dimension being smaller than the first critical dimension.

In a second aspect of the invention, a method for etching a semiconductor device, includes etching the semiconductor device using a surface charging technique in combination with a plasma etch, such that nested features formed on the semiconductor device are etched faster than an isolated feature formed on the semiconductor device.

With the unique and unobvious aspects of the present invention, the tolerance of printing isolated features can be tightly controlled. Further, an existing dimension can be trimmed to a smaller dimension using an existing tool. Additionally, a charging mechanism can be used to correct the offset.

### BRIEF DESCRIPTION OF THE DRAWINGS

The foregoing and other purposes, aspects and advantages will be better understood from the following detailed description of preferred embodiments of the invention with reference to the drawings, in which:

FIGS. 1A-1D illustrates a conventional process of forming a gate;

FIGS. 2A-2B illustrate a structure 200 formed with a process according to the present invention;

FIG. 2C illustrates characteristics of the structure formed by the method of the present invention;

FIG. 3 is a flowchart of a method 300 according to the present invention used to form the structure of FIGS. 2A-2B;

FIG. 4 illustrates an electron surface charging for a negative resist; and

FIG. 5 is a flowchart of a method 500 according to the present invention used to form the structure of FIG. 4.

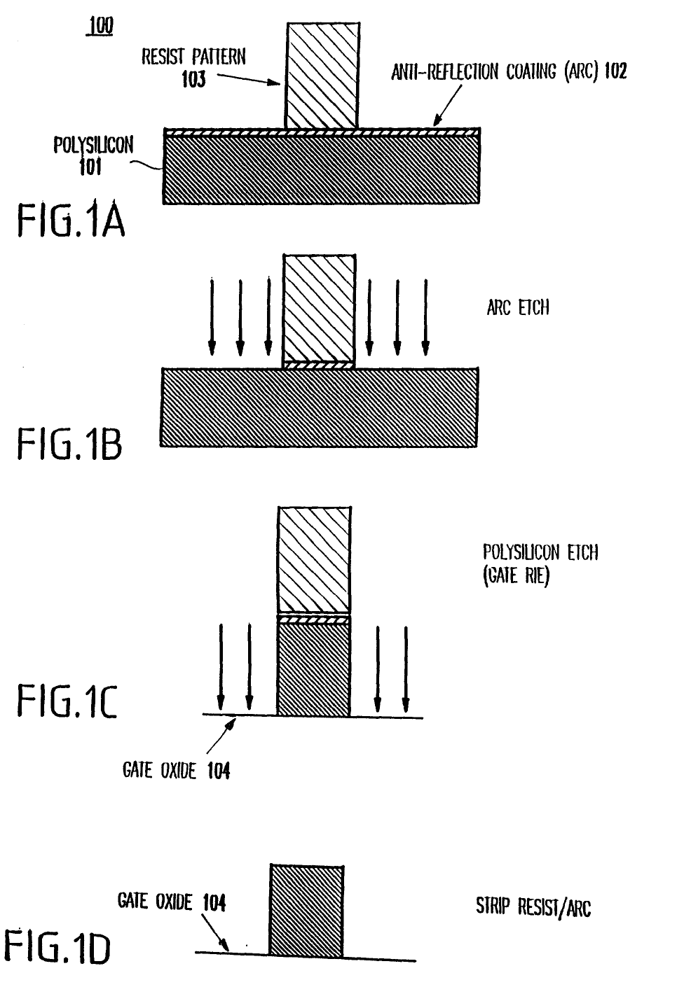

### DETAILED DESCRIPTION OF PREFERRED EMBODIMENTS OF THE INVENTION

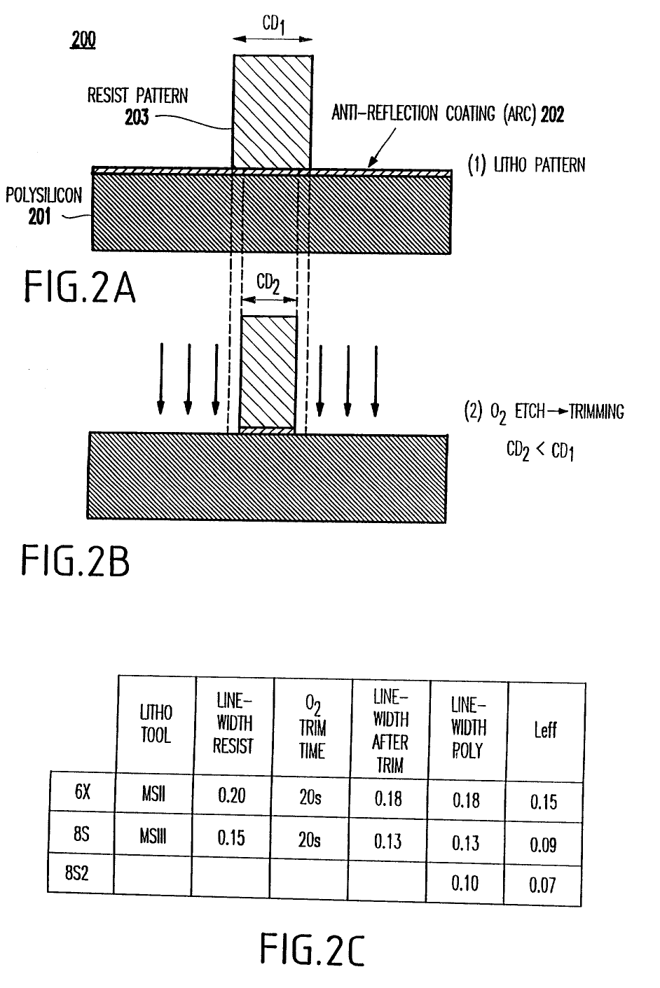

Referring now to the drawings, and more particularly to FIGS. 2A-5, there are shown preferred embodiments of the method and structures according to the present invention.

As mentioned above, generally the invention provides a method for not only extending the gate critical dimension shrinking roadmap with the current lithographic capability without sacrificing the total tolerance control, but also of correcting the inherent (e.g., optical property of light reflection isolated nested offset from lithographic processes.

It is noted that for purposes of the present application, “offset” is defined as the error which occurs when printing or forming one feature to another feature. Thus, when printing features on a wafer (or chip), there may be a high pattern density (e.g., high loading in one area of the wafer/chip) whereas another area of the wafer may have a low loading. The nature of the optics in printing the pattern may be error-prone, thereby changing the dimensions, changing the dose enriching the surface and changing the photoresist dimensions, etc. However, as mentioned above, hitherto the invention, regardless of how the offset was attempted to be controlled in the past, there would still be inherent problems from the optical lithography process standpoint and problems still occurred.

Turning to FIGS. 2A-2B, a novel oxygen (e.g., O₂)-containing etching process of the invention allows trimming the critical PC lithographic dimension to a smaller geometry uniformly across chip, wafers and lots.

That is, the sputtering component (e.g., O₂) of this unique process not only can shrink the existing photoresist pattern to a much smaller linewidth depending on the trimming time, but also corrects the nested-isolated offset inherent from lithographic processes. This etch allows such a correction because an O₂-containing etch allows the designer to see an offset between the nested and isolated features.

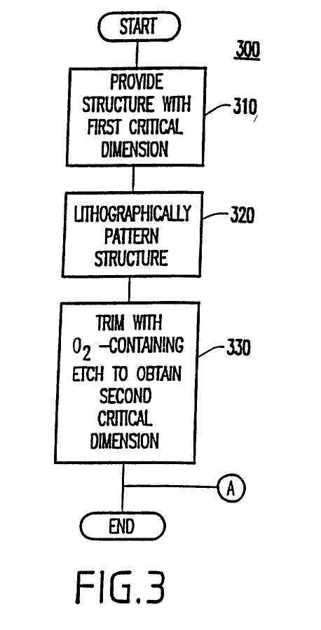

As shown in FIG. 2A (and referring to the flowchart of FIG. 3 which corresponds to the processing steps of FIGS. 2A-2B), first a structure 200 is provided (e.g., step 310) having a polysilicon substrate 201, an antireflection coating (ARC) 202 (e.g., an organic or an inorganic material), and a resist pattern 203 formed on the ARC 202 and having a first critical dimension (CD1). For purposes of the present invention, a “first critical dimension” is a dimension of whatever (e.g., device feature) is formed on silicon. That is, it is not necessarily how much is printed. What is printed is not necessarily the final feature size/dimension. That is, when the industry commonly quotes a size of 0.13 microns, 0.18 microns, 0.25 microns, etc., it only represents the generation for the lithographic processes able to target and not necessarily the final feature size on the device. Hence, normally the feature of the device on the surface will be smaller than the size quoted. Thus, the critical feature is what is to be placed on the silicon (e.g., on the substrate).

Thus, the ARC 202 has a minimum reliable linewidth (e.g., in a range of 10%-15% of controlling linewidth), and a lithography pattern is formed on the photoresist.

As shown in FIG. 2A, in step 320, the structure is lithographically patterned.

Thereafter, as shown in FIG. 2B (step 330 of the flowchart of FIG. 3), the ARC 202 is etched via a gas containing O₂ to perform trimming of the first critical dimension to obtain a “second critical dimension”. For purposes of the present application, the “second critical dimension” has a smaller width (e.g., about 10-50 nm smaller) than the first critical dimension. Such an etch is critical for line with bias and the nested-isolated feature offset.

O₂-containing etching is preferably performed at about 5 mT to about 50 mT for about 5 seconds to about 40 seconds, such that no loss of control results. Thus, the etching rate should be within a specified limit and should not be too fast, otherwise there will be no time to respond to make the adjustments to the etching process. Generally, the rate is proportional to how much resist is being used and the amount of the ARC layer 202 to be used. Thus, if the ARC 202 is thick, then a higher etch rate is allowable, whereas if the ARC layer 202 is very thin, then the etch rate must be strictly controlled to a low rate.

It is again noted that an O₂-containing etch is better than other chemistries employed in RIE or another plasma etch because it is a very directional etch (e.g., highly selective) and has more ion-assisted etching, and is more selective to silicon than to photoresist (organic material). Again, the oxygen-containing etch allows the offset between nested and isolated features to be overcome, thereby providing a key advantage of the invention over the conventional techniques.

Further, it is noted that the oxygen containing etch is not necessarily a pure O₂ etch, but instead preferably is mixed with 5% CFO (e.g., for increased plasma stability).

The above-described inventive trimming process can benefit greatly with corrected positive photoresist process, in which isolated features is printed larger than nested feature due to the total amount of light reflection from reticle clearance.

With the process of the invention, many advantages accrue including enabling a smaller critical dimension.

Further, there is uniformity and consistency across chips, wafers and pitches. For a positive resist, Lwiso>Lwnest, lateral sputtering results in etched Lwiso>Lwnest, and improved nested-isolated offset which means greater than across chip linewidth variation (ACLV).

FIG. 2C is a graph illustrating various lithographic tools (e.g., MSII, which is a previous generation micro scan (MS) lithographic tool using, for example, deep ultraviolet rays and MSIII being a next generation tool). Regarding the tools, every generation of tools depend on the optics, wavelength available, etc., and have their own characteristics on how they print the features. FIG. 2C shows also final linewidth change with different trimming times.

As mentioned above, FIG. 3 illustrates a flowchart of the above-described method 300 according to the present invention used to form the structure of FIGS. 2A-2B.

Second Embodiment

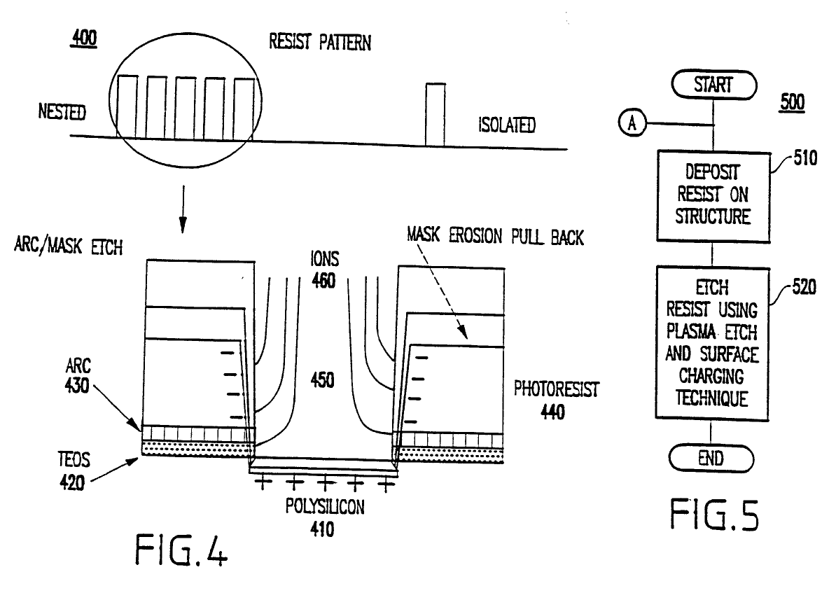

In a second aspect of the invention, it has been recognized that conversely to the situation described above, nested features consistently are printed larger than isolated features with a negative resist photo process. FIG. 4 illustrates the charging mechanism during a mask etch.

Thus, a second aspect of the invention is directed to an innovative technique based on an electron surface charging mechanism to correct the offset (e.g., thereby trimming a nested feature faster than an isolated feature).

Turning to FIG. 4 (and the flowchart of FIG. 5), a structure 400 is shown having a polysilicon substrate 410. A TEOS layer 420 and an ARC layer 430 are formed over the polysilicon 410, and a photoresist 440 is formed over the ARC (step 510).

As shown, the TEOS, ARC, and photoresist are etched to form a cavity 450 therebetween (step 520).

During the polysilicon conductor (PC) hardmask 440 (e.g., having a thickness on the order of about 500 Å oxide) etch, ions 460 generated from the plasma (e.g., NF₃/Ar) etch oxide into polysilicon film 410 with minimum selectivity. The mixture of the NF₃ to the argon can be varied such that the charging effect depends upon the characteristics of the chemistry and such gases may exist in different pluralities. Other gases may be employed as well including an electron negative charge plasma capable of performing the polysilicon and oxide etch.

Hence, in the process, ions are initially more collimated than electrons (e.g., because there is an absence of an electric field near the top of the structure and as the etch continues the ions will be deflected by the buildup of charge along the walls of the structure, as shown in FIG. 4). Thus, as the etch continues, charge gradually builds up on the wall of the nested line creating electric field(s). Subsequently, ions are deflected by the electric field(s) to cause lateral etching (e.g., on the walls of the ARC/TEOS/mask between the nested features and the isolated features). Thus, the etch is angled the deeper that the ions enter the well/cavity.

Due to both mask erosion and mask pull-back, nested features etch faster than isolated features, which compensate for the nested-isolated offset from negative photo resist process.

Mask erosion occurs in that the etch in this aspect of the invention is not selective as in the first aspect of the invention. That is, this type of chemistry also etches the mask and both of the materials in a similar fashion. Thus, there is no selectivity as to any material in the etching. Hence, when performing the etching, a top corner may exist at, for example, a 45-degree angle and there will be a higher etch rate, and an erosion of the top comer will occur. Depending upon the thickness of the mask (e.g., if it is relatively thin), there will be a pull-back of the mask during the etching.

Hence, again the nested features will etch faster, and the nested-isolated feature effect will be compensated. FIG. 5 is a flowchart of a method 500 according to the present invention used to form the structure of FIG. 4.

It is noted that, while the charging phenomena may not be new, using it in the method of the present invention allows great benefits not previously recognized or deemed possible with the charging phenomena. Indeed, the industry has attempted to avoid the charging phenomena in the past. In contrast, the invention affirmatively uses electron surface charging to great benefit and advantage, as described above.

Thus, the present invention is a departure from the methods typically employed in the industry. That is, most competitors in the industry are pushing the current lithography process to its limit by trading off the manufacturing yield for high-end component in return for a higher profit margin. With the present invention, a high performance part can be produced without compromising the yield.

To provide tolerance control in terms of linewidth control, many companies with high volume part choose optical proximity correction (OPC) to rectify the offset and customer design to avoid any critical path. Thus, the invention is optimized over such techniques.

While the invention has been described in terms of preferred embodiments, those skilled in the art will recognize that the invention can be practiced with modification within the spirit and scope of the appended claims.

What is claimed is:

1. A method of forming a semiconductor device, comprising:
providing a structure having a first critical dimension;
forming a lithographic pattern on said structure; and
etching said structure with an O₂-containing material to trim said first critical dimension to a second critical dimension, said second critical dimension being smaller than said first critical dimension.

2. The method of claim 1, further comprising:
correcting an offset between a nested feature printed on said structure and an isolated feature printed on said structure

3. The method of claim 1, further comprising:
forming a positive photoresist over said structure prior to forming said lithographic pattern on said structure.

4. The method of claim 2, wherein said correcting includes:
forming a negative photoresist over said nested feature and said isolated feature; and
etching said semiconductor substrate using a surface charging technique in combination with a plasma etch, such that said nested feature is etched faster than said isolated feature.

5. The method of claim 1, wherein said second critical dimension is within a range of about 10-50 nm smaller than said first critical dimension.

6. The method of claim 1, wherein said etching is performed at approximately 5 mT to approximately 50 mT for a time of between approximately 5 seconds to approximately 40 seconds.

7. The method of claim 1, wherein said structure includes an anti-reflection coating formed on a polysilicon substrate.

8. A method of trimming a conductor on a substrate, comprising:
providing a conductor having a first critical dimension;
forming a lithographic pattern on said conductor; and
etching said conductor with an O₂-containing material to trim said first critical dimension to a second critical dimension, said second critical dimension being smaller than said first critical dimension.

9. The method of claim 8, further comprising:
correcting an offset between a nested feature printed on said conductor and an isolated feature printed on said conductor.

10. The method of claim 8, further comprising:
forming a positive photoresist over said conductor prior to forming said lithographic pattern on said conductor.

11. The method of claim 8, wherein said second critical dimension is within a range of about 10-50 nm smaller than said first critical dimension.

12. The method of claim 8, wherein said etching is performed at approximately 5 mT to approximately 50 mT for a time of between approximately 5 seconds to approximately 40 seconds.

13. The method of claim 8, wherein said conductor includes a polysilicon substrate having an anti-reflection coating formed thereon.

14. A method of etching a semiconductor device, comprising:
etching said semiconductor device using a surface charging technique in combination with a plasma etch, such that a nested feature formed on said semiconductor device is etched faster than an isolated feature formed on said semiconductor device.

15. The method of claim 14, wherein said etching said nested feature faster corrects an offset between said nested feature and said isolated feature.

16. The method of claim 14, wherein a negative photoresist is provided over said nested feature and said isolated feature.

17. The method of claim 14, wherein said etching uses a mixture of NF₃ and argon.

18. The method of claim 14, wherein said semiconductor device includes a polysilicon substrate, a TEOS layer formed over the substrate, and an antireflection coating layer formed over the substrate.

19. A method of etching a semiconductor material, comprising:
providing a semiconductor substrate including a nested feature and an isolated feature;
forming a negative photoresist over said nested feature and said isolated feature; and
etching said semiconductor substrate using a surface charging technique in combination with a plasma etch, such that said nested feature is etched faster than said isolated feature.

20. The method of claim 19, wherein said semiconductor substrate includes a polysilicon substrate, and wherein a TEOS layer and an antireflection coating layer are formed over the substrate.
